(19) United States
(12) Patent Application Publication
(10) Pub. No.: US 2023/0305068 A1
(43) Pub. Date: Sep. 28, 2023

(54) BATTERY INFORMATION MANAGEMENT METHOD AND STORAGE MEDIUM

(71) Applicant: HONDA MOTOR CO., LTD., Minato-ku, Tokyo (JP)

(72) Inventors: Yukiko Onoue, Wako-shi, Saitama (JP); Tsubasa Uchida, Tokyo (JP); Keita Sera, Wako-shi, Saitama (JP)

(21) Appl. No.: 18/095,594

(22) Filed: Jan. 11, 2023

(30) Foreign Application Priority Data
Jan. 14, 2022 (JP) 2022-004319

(51) Int. Cl. G01R 31/367

(52) U.S. Cl. CPC G01R 31/367; G01R 31/371

(57) ABSTRACT

Provided is a battery information management including: acquiring battery information including: measurement data including a measurement result relating to electrical characteristics of a battery; an algorithm for evaluating the state of the battery from the measurement data; and evaluation data including the result of evaluating the state of the battery by the algorithm; executing first processing of calculating a first hash value that is a hash value of at least one of the measurement data and the algorithm included in the battery information; executing second processing of calculating a second hash value that is a hash value of package data associating the first hash value with the evaluation data; and executing third processing of storing at least one of the measurement data and the algorithm into a database in a searchable manner with the second hash value serving as a key.

### CROSS-REFERENCE TO RELATED APPLICATION

The application is based on Japanese Patent Application No. 2022-004319 filed on Jan. 14, 2022, the content of which incorporated herein by reference.

### BACKGROUND

### Field of the Invention

The present invention relates to a battery information management method and a storage medium.

### Description of Related Art

Hitherto, there has been known the technology of reliably managing information on the performance of a battery mounted in a vehicle. For example, International patent application laid-open No. 2021/010092 discloses the technology of recording performance information on a secondary battery into a distributed database network such as a blockchain in a tamper-proof manner.

### SUMMARY

However, when battery performance information is managed reliably by using a distributed database network such as a blockchain as in the related art, there has been a problem in that the management technique becomes complex and the management cost increases.

The present invention has been made in view of the above-mentioned circumstances, and has an object to provide a battery information management method and a storage medium that are capable of reliably managing battery performance information with a simpler method at a low cost.

A battery information management method and a storage medium according to the present invention adopt the following configuration.

(1): A battery information management method according to one aspect of the present invention is a battery information management method to be executed by at least one computer, the battery information management method including: acquiring battery information including: measurement data including a measurement result relating to electrical characteristics of a battery; an algorithm for evaluating the state of the battery from the measurement data; and evaluation data including the result of evaluating the state of the battery by the algorithm; executing first processing of calculating a first hash value that is a hash value of at least one of the measurement data and the algorithm included in the battery information; executing second processing of calculating a second hash value that is a hash value of package data associating the first hash value with the evaluation data; and executing third processing of storing at least one of the measurement data and the algorithm into a database in a searchable manner with the second hash value serving as a key.

(2): In the aspect (1), the at least one computer executes the second processing of calculating the second hash value by including, in the package data, data relating to a date and time of acquisition of the battery information or calculation of the first hash value.

(3): In the aspect (1), the at least one computer executes the first processing and the second processing every time the measurement result relating to electrical characteristics of the battery is generated, and the at least one computer executes the third processing of storing, into the database, the first hash and the second hash value, which are calculated by the first processing and the second processing executed for the same battery, in association with each other.

(4): In the aspect (1), the at least one computer executes fourth processing of calculating a third hash value that is a hash value of the measurement data in a device including the battery, and the first processing includes processing of acquiring the third hash value.

(5): A non-transitory computer-readable medium according to one aspect of the present invention is a non-transitory computer-readable medium storing a program for causing at least one computer to: acquire battery information including: measurement data including a measurement result relating to electrical characteristics of a battery; an algorithm for evaluating the state of the battery from the measurement data; and evaluation data including the result of evaluating the state of the battery by the algorithm; execute first processing of calculating a first hash value that is a hash value of at least one of the measurement data and the algorithm included in the battery information; execute second processing of calculating a second hash value that is a hash value of package data associating the first hash value with the evaluation data; and execute third processing of storing at least one of the measurement data and the algorithm into a database in a searchable manner with the second hash value serving as a key.

According to the aspects (1) to (5), it is possible to reliably manage battery performance information with a simpler method at a low cost.

According to the aspect (2), it is possible to further improve the reliability of the battery performance information.

According to the aspect (3), it is possible to manage the history of specific battery performance information.

According to the aspect (4), it is possible to improve tamper resistance of the battery performance information.

### BRIEF DESCRIPTION OF THE DRAWINGS

FIG. 1 is a diagram illustrating an example of the configuration of a vehicle to which a battery information management device according to a first embodiment is applied.

FIG. 2 is a diagram illustrating an example of the configuration of the battery information management device according to the first embodiment.

FIG. 3 is a diagram illustrating an example of the configuration of measurement data.

FIG. 4 is a diagram illustrating an example of the configuration of a market data DB.

FIG. 5 is a diagram illustrating an example of the configuration of an internal DB.

FIG. 6 is a diagram illustrating an example of the flow of processing to be executed by the battery information management device.

FIG. 7 is a diagram illustrating an example of the configuration of a system including a vehicle to which a battery information management device according to a second embodiment is applied.

FIG. 8 is a block diagram illustrating an example of the configuration of a removable battery.

FIG. 9 is a diagram illustrating an example of a use case of the present invention.

FIG. 10 is a diagram illustrating another example of the use case of the present invention.

### DESCRIPTION OF EMBODIMENTS

Now, referring to the drawings, description is given of a battery information management method and a storage medium according to an embodiment of the present invention.

### First Embodiment

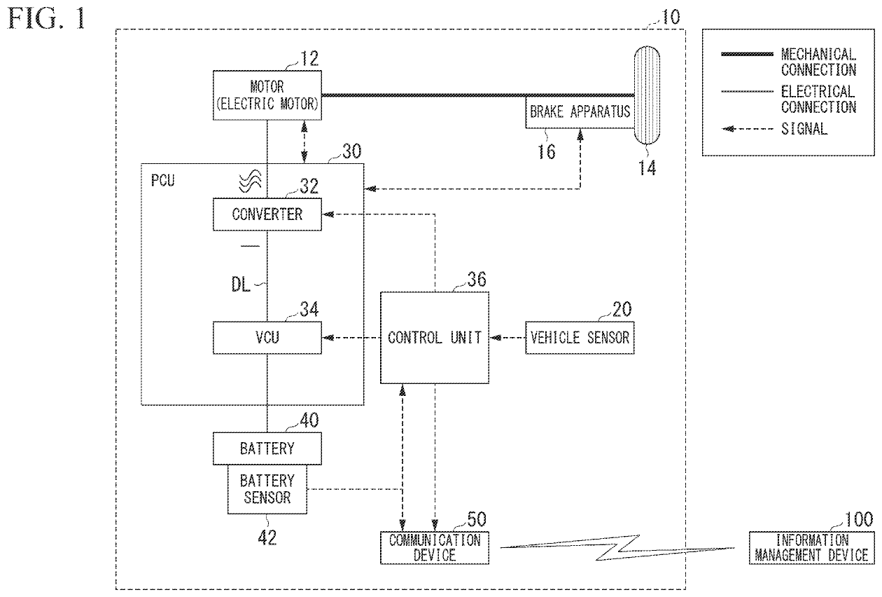

FIG. 1 is a diagram illustrating an example of the configuration of a vehicle 10 to which a battery information management device 100 according to an embodiment is applied. The vehicle 10 illustrated in FIG. 1 is a battery electric vehicle (BEV) traveling using a motor (electric motor) driven by power supplied from a battery (secondary battery) for traveling. Alternatively, the vehicle 10 may be a plug-in hybrid vehicle (PHV) or a plug-in hybrid electric vehicle (PHEV), which is a hybrid vehicle having an external charging function. Alternatively, the vehicle 10 may be a plug-in hybrid vehicle (PHV) or a plug-in hybrid electric vehicle (PHEV), which is a hybrid vehicle having an external charging function. The vehicle 10 includes, for example, not only a four-wheeled vehicle, but also a saddle-riding two-wheeled vehicle, a three-wheeled vehicle (including a vehicle with two front wheels and one rear wheel in addition to a vehicle with one front wheel and two rear wheels), an assisted bicycle, and even an electric boat. The vehicle 10 includes any type of mobile object that travels using an electric motor driven by power supplied from a battery.

A motor 12 is, for example, a three-phase AC motor. The rotor of the motor 12 is connected to a driven wheel 14. The motor 12 is driven by power supplied from an accumulation unit (not shown) included in a battery 40, and transmits the rotational force to the driven wheel 14. Further, the motor 12 generates power using kinetic energy of the vehicle 10 at the time of deceleration of the vehicle 10.

A brake apparatus 16 includes, for example, a brake caliper, a cylinder that transmits hydraulic pressure to the brake caliper, and an electric motor that generates hydraulic pressure in the cylinder. The brake apparatus 16 may be equipped with a mechanism as a backup, which transmits the hydraulic pressure generated by the operation by the user (driver) of the vehicle 10 against a brake pedal (not shown) to the cylinder via the master cylinder. The brake apparatus 16 is not limited to the configuration described above, but may be an electronically controlled hydraulic brake apparatus that transmits the hydraulic pressure from the master cylinder to the cylinder.

A vehicle sensor 20 includes, for example, an accelerator position sensor, a vehicle speed sensor, and a brake depression amount sensor. The accelerator position sensor is mounted to the accelerator pedal, detects the amount of operation of the accelerator pedal by the driver, and outputs the detected amount of operation as the accelerator position to a control unit 36 described later. The vehicle speed sensor includes, for example, a wheel speed sensor mounted to each wheel of the vehicle 10 and a speed calculator, which integrates the wheel speeds detected by the wheel speed sensors to derive the speed (vehicle speed) of the vehicle 10 for output to the control unit 36. A brake depression amount sensor is mounted to the brake pedal, and detects the amount of operation of the brake pedal by the driver, and outputs the detected amount of operation to the control unit 36 as a brake depression amount.

A PCU 30 includes, for example, a converter 32 and a voltage control unit (VCU) 34. In FIG. 1, these components in the vehicle 10 are shown in a single component as the PCU 30 as an example, and may be arranged in a distributed manner.

The converter 32 is, for example, an AC-DC converter. The terminal of the converter 32 on the direct current side is connected to a direct current link DL. The direct current link DL is connected to the battery 40 via the VCU 34. The converter 32 converts alternating current generated by the motor 12 to direct current, and outputs the direct current to the direct current link DL.

The VCU 34 is, for example, a DC-DC converter. The VCU 34 increases the voltage of power supplied from the battery 40, and outputs the power to the direct current link DL.

The control unit 36 controls drive of the motor 12 on the basis of output from the accelerator position sensor included in the vehicle sensor 20. The control unit 36 controls the brake apparatus 16 on the basis of output from the brake depression amount sensor included in the vehicle sensor 20. The control unit 36 calculates, for example, an SOC (State Of Charge) of the battery 40 on the basis of output from a battery sensor 42 described later, which is connected to the battery 40, and outputs the SOC to the VCU 34. The VCU 34 increases the voltage of the direct current link DL in response to an instruction from the control unit 36.

The battery 40 is a secondary battery capable of repeatedly charging and discharging, such as a lithium ion battery. The battery 40 may be, for example, a cassette type battery pack, which is removably mounted to the vehicle 10. The battery 40 stores power supplied from a charger (not shown) outside of the vehicle 10, and discharges power for traveling of the vehicle 10.

The battery sensor 42 detects a physical quantity such as current, voltage, and temperature of the battery 40. The battery sensor 42 includes, for example, a current sensor, a voltage sensor, and a temperature sensor. The battery sensor 42 detects a current of the second battery constructing the battery 40 (hereinafter simply referred to as “battery 40”) by using the current sensor, detects a voltage of the battery 40 by using the voltage sensor, and detects a temperature of the battery 40 by using the temperature sensor. The battery sensor 42 outputs data of the physical quantity such as the detected current value, voltage value, and temperature of the battery 40 to the control unit 36 or a communication device 50.

The communication device 50 includes a wireless module for connecting to a cellular network or a Wi-Fi network. The communication device 50 may also include a wireless module for using Bluetooth (trademark) or the like. The communication device 50 transmits/receives various kinds of information on the vehicle 10 to/from, for example, the battery characteristic estimation device 100 through communication using the wireless module. For example, the communication device 50 transmits, to the battery information management device 100, measurement data such as the current value, voltage value, or temperature of the battery 40 measured by the battery sensor 42 or the SOC calculated by the control unit 36 in association with a vehicle identification number (VIN) for identifying the vehicle 10 or a battery ID for identifying the battery 40.

[Configuration of Battery Information Management Device]

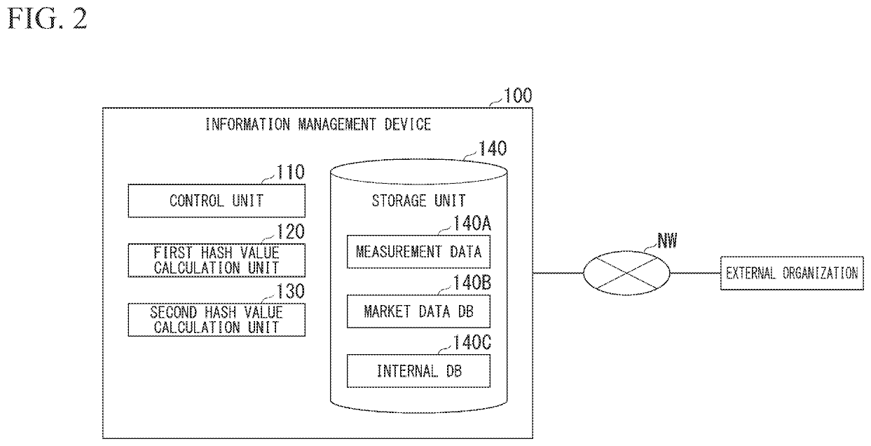

Next, description is given of an example of the battery information management device 100 for managing information on the battery 40 of the vehicle 10. FIG. 2 is a diagram illustrating an example of the configuration of the battery information management device 100 according to the embodiment. The battery information management device 100 includes, for example, a control unit 110, a first hash value calculation unit 120, and a second hash value calculation unit 130. The control unit 110, the first hash value calculation unit 120, and the second hash value calculation unit 130 are implemented by a hardware processor such as a CPU (Central Processing Unit) executing a program (software), for example. A part or all of these components may be implemented by hardware (circuit unit including circuitry) such as an LSI (Large Scale Integration), an ASIC (Application Specific Integrated Circuit), an FPGA (Field-Programmable Gate Array), or a GPU (Graphics Processing Unit), or may be implemented through cooperation between software and hardware. The program may be stored in a storage device (storage device including non-transitory storage medium) such as an HDD (Hard Disk Drive) or flash memory in advance, or may be stored in a removable storage medium (non-transitory storage medium) such as a DVD or CD-ROM and the storage medium may be attached to a drive device to install the program. The storage unit 140 is, for example, an HDD, a flash memory, or a random access memory (RAM). The storage unit 140 stores, for example, measurement data 140A, a market data DB 140B, and an internal DB 140C.

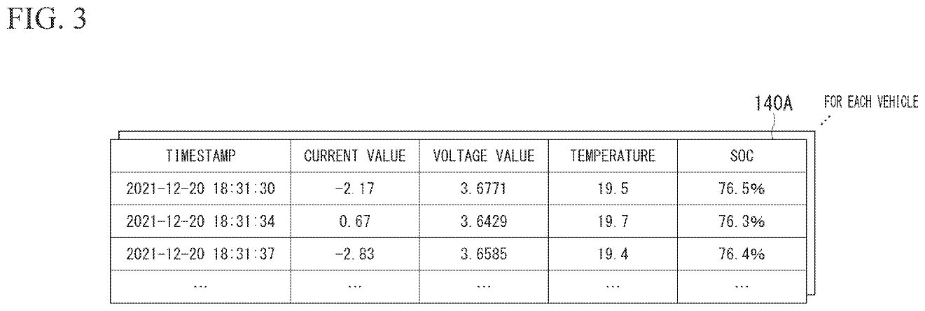

The control unit 110 acquires, from the communication device 50 of the vehicle 10, measurement data 140A including a measurement result relating to electrical characteristics of the battery. FIG. 3 is a diagram illustrating an example of the configuration of the measurement data 140A. The measurement data 140A is recorded for each vehicle 10, and is information in which the current value, voltage value, temperature, SOC, and the like are associated with a time stamp indicating a time at which the measurement data 140A is acquired. The measurement data 140A is, for example, information recorded over the period of one month.

The control unit 110 evaluates the state of the battery 40 of the vehicle 10 on the basis of the acquired measurement data 140A. For example, the control unit 110 calculates, as evaluation of the state of the battery 40 of the vehicle 10, a SOH (State Of Health) indicating the ratio of a full charge capacity at the time of degradation of the battery 40 with an initial full charge capacity [Ah] of the battery 40 being 100%. The initial full charge capacity is, for example, a full charge capacity at the time of shipment of the battery 40. The control unit 110 stores the calculated SOH into the market data DB 140B.

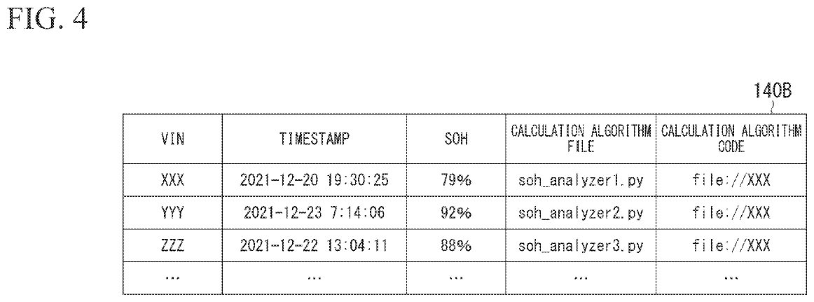

FIG. 4 is a diagram illustrating an example of the configuration of the market data DB 140B. The market data DB 140B is, for example, information in which a timestamp, an SOH, a calculation algorithm file, and a calculation algorithm code are associated with the VIN. The time stamp indicates the time at which the SOH is calculated (or latest time indicated by time stamp of measurement data 140A used for calculating SOH). The SOH indicates a value calculated by the control unit 110 on the basis of the measurement data 140A. The calculation algorithm file indicates the name of a file (for example, Python file) of the SOH calculation algorithm used for calculating the SOH. The calculation algorithm code indicates the path of a file storing the SOH calculation algorithm. Alternatively, the market data DB 140B may store the execution code of the SOH calculation algorithm itself instead of the path of the file storing the SOH calculation algorithm.

The first hash value calculation unit 120 calculates the hash value of the measurement data 140A of the vehicle 10 by using any hash function. More specifically, for example, the first hash value calculation unit 120 reads a measurement data file (for example, CSV file) stored in the measurement data 140A of the vehicle 10, and applies the hash function to the measurement data file to calculate the hash value of the measurement data 140A. The first hash value calculation unit 120 stores the calculated hash value of the measurement data 140A into the internal DB 140C in association with the VIN and file name of the measurement data file (and/or path to the file).

The first hash value calculation unit 120 calculates the hash value of the calculation algorithm that is stored in the market data DB 140B and used for calculating the SOH of the vehicle 10. More specifically, for example, the first hash value calculation unit 120 reads the calculation algorithm file storing the calculation algorithm used for calculating the SOH of the vehicle 10, and applies the hash function to the calculation algorithm to calculate the hash value of the calculation algorithm. The first hash value calculation unit 120 stores the calculated hash value of the calculation algorithm into the internal DB 140C in association with the VIN and file name of the calculation algorithm file (and/or path to the file).

In this embodiment, the first hash value calculation unit 120 calculates the hash value of the measurement data 140A and the hash value of the calculation algorithm. However, the present invention is not limited to such a configuration, and it suffices that the first hash value calculation unit 120 calculates at least one of the hash value of the measurement data 140A and the hash value of the calculation algorithm. The at least one of the hash value of the measurement data 140A and the hash value of the calculation algorithm is an example of “first hash value”.

The second hash value calculation unit 130 generates package data (for example, CSV file recording hash value of measurement data 140A, hash value of calculation algorithm, and SOH) associating the hash value of the measurement data 140A and the hash value of the calculation algorithm calculated by the first hash value calculation unit 120 with the SOH stored in the market data DB 140B, and applies a hash function to the package data to calculate the hash value of the SOH. The second hash value calculation unit 130 stores the calculated hash value of the SOH into the internal DB 140C in association with the VIN and file name of the SOH (and/or path to the file).

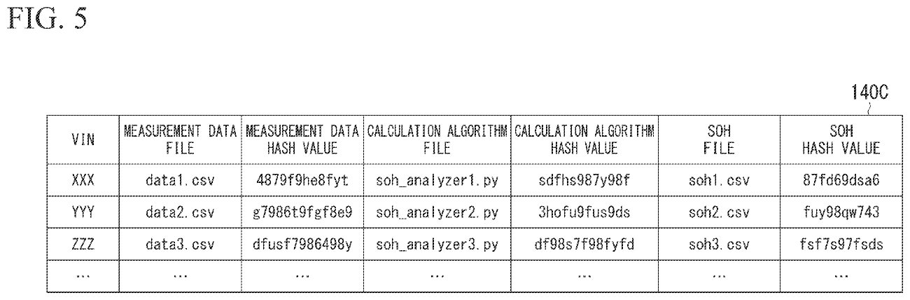

FIG. 5 is a diagram illustrating an example of the configuration of the internal DB 140C. The internal DB 140C associates, for example, the VIN with information such as the above-mentioned measurement data file, measurement data hash value, calculation algorithm hash value, SOH file (file corresponding to above-mentioned “package data”), and SOH hash value.

As illustrated in FIG. 5, the internal DB 140C is configured such that the SOH hash value is used as a search key to search for the corresponding measurement data 140A and calculation algorithm. The internal DB 140C is a database that restricts the right of access to the battery information management device 100 by the user more strictly than the market data DB 140B.

Referring back to FIG. 2, the control unit 110 provides the SOH stored in the market data DB 140B and the SOH hash value stored in the internal DB 140C to an external organization (for example, legal authorities and car dealers) regularly or in response to a request via any network NW such as the Internet.

The processing of the first hash value calculation unit 120 and the second hash value calculation unit 130 described above is executed every time the measurement data 140A is received from the communication device 50 of the vehicle 10. When the measurement data 140A is received from the communication device 50 of the vehicle 10, the first hash value calculation unit 120 calculates a first hash value on the basis of the received measurement data 140A, and the second hash value calculation unit 130 calculates a second hash value on the basis of the calculated first hash value and SOH, and stores the calculated first hash value and second hash value into the internal DB 140C in association with the VIN of the vehicle 10 for which these hash values are calculated. As a result, it is possible to keep the first hash value and the second hash value in the latest state according to update of the measurement data 140A.

In this embodiment, the second hash value calculation unit 130 applies a hash function to the package data including the hash value of the measurement data 140A, the hash value of the calculation algorithm, and the SOH. However, the present invention is not limited to such a configuration, and the date and time (for example, latest date and time of timestamp) at which the measurement data 140A is acquired or the date and time at which the first hash value is calculated may be included in the package data to calculate the hash value of the package data. As a result, it is possible to improve security of the hash value.

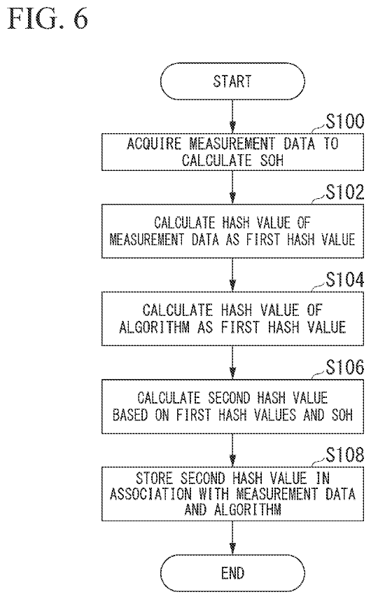

Next, referring to FIG. 6, description is given of a flow of processing to be executed by the battery information management device 100. FIG. 6 is a diagram illustrating an example of the flow of processing to be executed by the battery information management device 100.

First, the control unit 110 acquires the measurement data 140A of the battery 40 from the communication device 50 of the vehicle 10, and calculates the SOH of the vehicle 10 by using an SOH calculation algorithm corresponding to the vehicle 10 (Step S100). Next, the first hash value calculation unit 120 reads a measurement data file storing the measurement data 140A, and applies a hash function to the measurement data file to calculate the hash value of the measurement data 140A as a first hash value (Step S102).

Next, the first hash value calculation unit 120 reads a calculation algorithm file storing the calculation algorithm, which has been used at the time of calculating the SOH of the vehicle 10, and applies the hash function to the calculation algorithm file to calculate the hash value of the calculation algorithm as the first hash value (Step S104). Next, the second hash value calculation unit 130 applies a hash function to package data including the calculated two first hash values and SOH, to thereby calculate a second hash value (Step S106). Next, the second hash value calculation unit 130 stores the calculated second hash value into the internal DB 140C in association with the measurement data 140A and calculation algorithm. In this manner, the processing of this flow chart is finished.

### Modification Example of First Embodiment

In the first embodiment described above, the vehicle 10 transmits the measurement data 140A measured by the battery sensor 42 to the battery information management device 100, and the battery information management device 100 uses the hash function to calculate the hash value of the received measurement data 140A. However, the present invention is not limited to such a configuration. As a modification example of the first embodiment, for example, the control unit 36 of the vehicle 10 may have a feature of using the hash function to calculate the hash value of the measurement data 140A. In that case, the communication device 50 transmits the measurement data 140A and the hash value thereof to the battery information management device 100, and the battery information management device 100 stores these sets of data into the storage unit 140. After that, the battery information management device 100 calculates the hash value of the calculation algorithm and the hash value of the SOH similarly to the first embodiment.

The first embodiment described above involves calculating the hash value of the measurement data 140A of the vehicle 10, calculating the hash value of the calculation algorithm used at the time of calculating the SOH based on the measurement data 140A, calculating the hash value of the SOH together with the hash value of the measurement data 140A and the hash value of the calculation algorithm, and storing these sets of data into a database such that the calculated hash value of the SOH can be used as a search key to retrieve the corresponding measurement data 140A and calculation algorithm. In this manner, it is possible to reliably manage battery performance information simply at a low cost.

### Second Embodiment

The first embodiment of the present invention is applied to battery information management of the vehicle 10 when the vehicle 10 is a BEV that travels by an electric motor. Meanwhile, the second embodiment of the present invention is applied to a case in which the vehicle 10 is an electric vehicle that travels by an electric motor driven by power supplied from a removable battery 510.

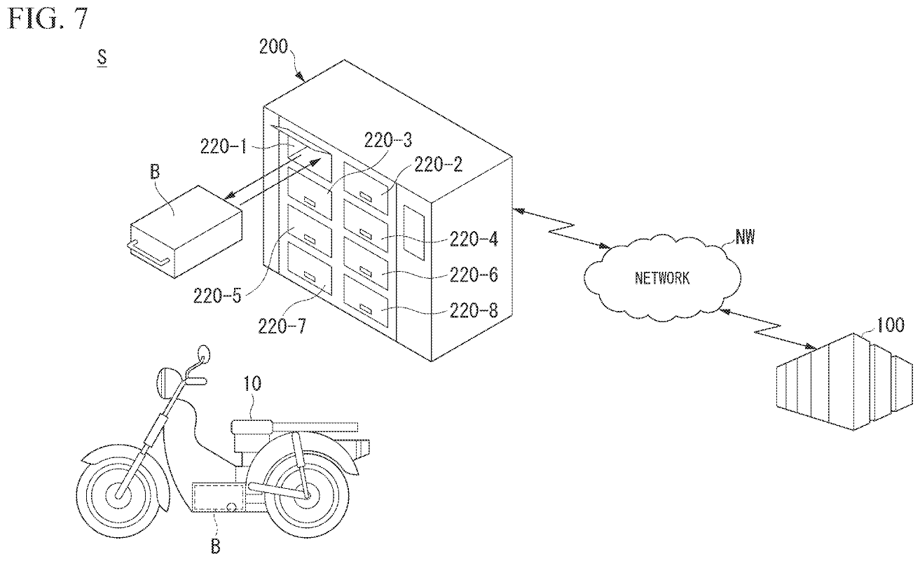

FIG. 7 is a diagram illustrating an example of the configuration of a system S including the vehicle 10 to which the battery information management device 100 according to the second embodiment is applied. As illustrated in FIG. 7, the system S includes a removable battery 510, a battery information management device 100, and a battery exchanger 200 (BEX). The system S may have a configuration in which one battery information management device 100 handles a plurality of battery exchangers 200. However, only one battery exchanger 200 is illustrated in FIG. 1.

The removable battery 510 is a power storage device (rechargeable battery), for example, a cassette type, which is removably mounted to the vehicle 10. At least one removable battery 510 is mounted to one vehicle 10. In the following description, it is assumed that the vehicle 10 is an electric vehicle to which one removable battery 510 is mounted.

The removable battery 510 is shared by a plurality of electric vehicles. Identification information (hereinafter referred to as “battery ID” (battery identification information)) capable of identifying the removable battery 510 is exclusively assigned to the removable battery 510. The battery ID may be a serial number of the removable battery 510. The removable battery 510 is returned to and stored in any one of slots 220-1 to 220-8 of the battery exchanger 200.

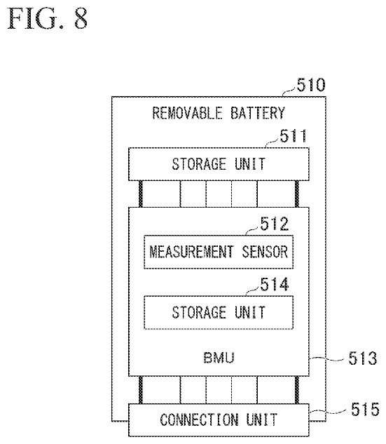

FIG. 8 is a block diagram illustrating an example of the configuration of the removable battery 510. As illustrated in FIG. 8, the removable battery 510 includes a power storage unit 511, a battery management unit (BMU) 513, and a connection unit 515. The BMU 513 includes a measurement sensor 512 and a storage unit 514.

The power storage unit 511 includes a battery that stores charged power and discharges stored power. The battery included in the power storage unit 511 is, for example, a secondary battery such as lead-acid batteries and lithium-ion batteries, capacitors such as electric double layer capacitors, or composite batteries combining secondary batteries and capacitors.

The measurement sensor 512 includes various sensors that measure the state of the storage unit 511. The measurement sensor 512 measures, for example, the voltage stored in the storage unit 511 by a voltage sensor. The measurement sensor 512 measures, for example, current flowing through the storage unit 511 by a current sensor. The measurement sensor 512 measures the temperature of the storage unit 511 when the storage unit 511 is charged or discharged by a temperature sensor. The sensor 512 measures, for example, by a temperature sensor, the temperature of the storage unit 511 when the storage unit 511 is charged or the storage unit 511 is discharged. The measurement sensor 512 outputs a measurement value representing the measured state of the storage unit 511 to a processor in the BMU 513.

The BMU 513 is a battery management unit that controls charging or discharging of the storage unit 511. The BMU 513 includes, as the storage unit 514, a processor such as a CPU (Central Processing Unit) and a memory such as a ROM (Read Only Memory) and a RAM (Random Access Memory). The BMU 513 implements the function of controlling the storage unit 511 by the CPU reading and executing a program stored in the storage unit 514. Then, the BMU 513 stores, into the storage unit 514, information such as details of control of the storage unit 511 based on the measurement value representing the state of the storage unit 511 output from the measurement sensor 512.

The storage unit 514 stores battery state information such as a battery ID assigned to the removable battery 510. In addition to the battery ID, the battery status information includes, for example, the number of charge cycles, date of manufacture, initial state capacity, charge rate, etc. The storage unit 514 stores information such as abnormalities and failures detected by the BMU 513 itself and abnormalities and failures of the storage unit 511 identified using the measurement sensor 512.

The connection unit 515 is a connection unit that supplies the electric power stored in the storage unit 511 to the electric motor that drives the vehicle 10 when the removable battery 510 is mounted to the vehicle 10. When the removable battery 510 is accommodated in the slot 220 included in the battery exchanger 200, the connection unit 515 is connected to structure for connecting to the removable battery 510 provided in the accommodation unit of the slot 220. The connection unit 515 also serves as a connection unit for transferring power or information such as the battery ID, number of times of charging, and measurement values representing the state of the energy storage unit 511 exchanged between the removable battery 510 and the battery exchanger 200.

The battery exchanger 200 is installed in a chagrining/exchange station (not shown). The chagrining/exchange station is installed in a plurality of locations, for example. The battery exchanger 200 communicates information with the battery information management device 100 through communication via any network NW such as the Internet. More specifically, for example, when the used removable battery 510 is returned, the battery exchanger 200 acquires, as the measurement data 140A, time-series data of the physical quantities such as the current value, voltage value, temperature, and SOC of the removable battery 510 measured by the BMU.

Next, the battery exchanger 200 uses any hash function to calculate the hash value of the measurement data 140A of the vehicle 10. The battery exchanger 200 further calculates the SOH of the removable battery 510 based on the measurement data 140A, and uses any hash function to calculate the hash value of the SOH calculation algorithm used at the time of calculating the SOH. The battery exchanger 200 transmits the calculated measurement data 140A, the hash value of the measurement data 140A, the value of the SOH, and the hash value of the SOH calculation algorithm to the battery information management device 100 via the network NW in association with the battery ID.

When the battery information management device 100 has received the hash value of the measurement data 140A, the value of the SOH, and the hash value of the SOH calculation algorithm, the battery information management device 100 uses any hash function to calculate the hash value (more specifically, for example, the hash value of a CSV file recording the hash value of the measurement data 140A, the hash value of the calculation algorithm, and the SOH) of the SOH based on the hash value of the measurement data 140A, the hash value of the SOH calculation algorithm, and the value of the SOH. Other processing is similar to the first embodiment.

According to the second embodiment described above, the battery exchanger 200 calculates the hash value of the measurement data 140A, the value of the SOH, and the hash value of the SOH calculation algorithm for transmission to the battery information management device 100, and the battery information management device 100 calculates the hash value of the SOH based on the received values, and stores these sets of data into a database such that the calculated hash value of the SOH can be used as a search key to retrieve the corresponding measurement data 140A and calculation algorithm. In this manner, it is possible to reliably manage battery performance information simply at a low cost.

[Use Case 1]

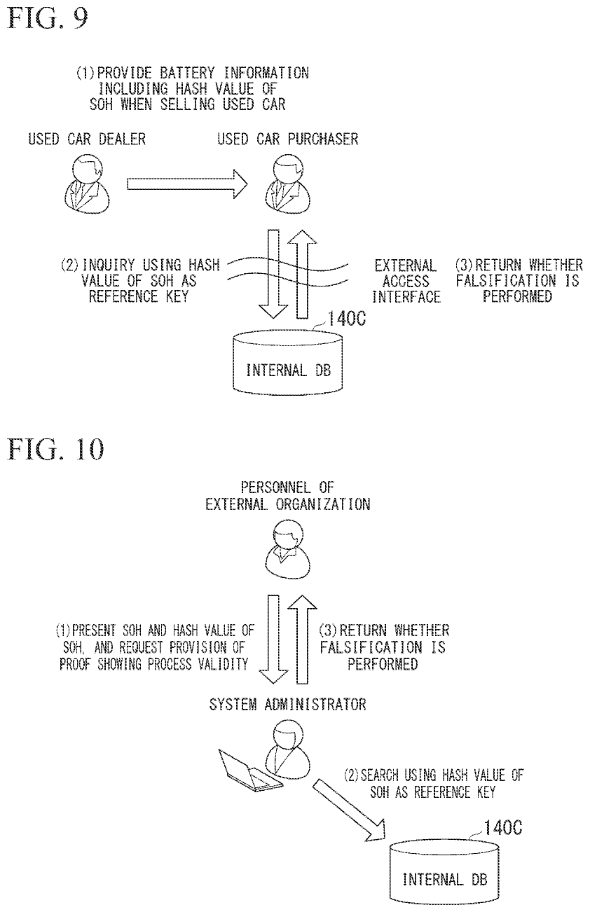

Next, description is given of use cases to which the present invention is applied with reference to FIG. 9 and FIG. 10. FIG. 9 is a diagram illustrating an example of a use case of the present invention. FIG. 9 represents a scene in which a used car dealer sells the vehicle 10, for which battery information is managed by the battery information management device 100 according to the present invention, to a used car purchaser. As illustrated in FIG. 9, when the used car dealer sells the vehicle 10 to a used car dealer, the used car dealer provides the value of the SOH and the hash value of the SOH, which are provided by the battery information management device 100, to the used car dealer together with a VIN (or battery ID).

Next, the used car purchaser uses, for example, his or her own terminal device to access an interface screen provided by the battery information management device 100, and inputs the VIN (or battery ID), the value of the SOH, and the hash value of the SOH into the interface screen. When the VIN (or battery ID), the value of the SOH, and the hash value of the SOH are input to the interface screen, these values are transmitted to the battery information management device 100, and the battery information management device 100 searches the market data DB 140B and the internal DB 140C.

When the input hash value of the SOH exists in the internal DB 140C and the value of the SOH stored in the market data DB 140B matches the input value, information to the effect that the SOH is not falsified is displayed on the interface screen. On the other hand, when the input hash value of the SOH does not exist in the internal DB 140C or the value of the SOH stored in the market data DB 140B does not match the input value, information to the effect that the SOH may be falsified is displayed on the interface screen. In this case, the interface screen may display the correct value of the SOH stored in the market data DB 140B.

[Use Case 2]

FIG. 10 is a diagram illustrating another example of the use case of the present invention. FIG. 10 represents a scene in which the personal of the external organization checks, for the vehicle 10, for which battery information is managed by the battery information management device 100 according to the present invention, the validity of a process for managing the battery information. As illustrated in FIG. 10, first, the personal of the external organization provides the value of the SOH and the hash value of the SOH, which are provided by the battery information management device 100, to a system administrator together with a VIN (or battery ID).

Next, the system administrator of the battery information management device 100 uses the VIN (or battery ID), the value of the SOH, and the hash value of the SOH to search the market data DB 140B and the internal DB 140C. When the hash value of the SOH exists in the internal DB 140C and the value of the SOH stored in the market data DB 140B matches the provided value, it is determined that the value of the SOH is not falsified, and an SOH calculation process including a series of data such as the measurement data 140A and the calculation algorithm is presented to complete verification.

On the other hand, when the hash value of the SOH does not exist in the internal DB 140C or the value of the SOH stored in the market data DB 140B does not match the provided value, the system administrator of the battery information management device 100 uses the measurement data 140A and a specified SOH calculation algorithm to recalculate the SOH, and provides the recalculated SOH and the process information to the personal of the external organization. In this process, the system administrator of the battery information management device 100 recalculates the hash value of the measurement data 140A, the hash value of the SOH calculation algorithm, and the hash value of the SOH, and compares the values with true values stored in the internal DB 140C, to thereby also be capable of identifying and proving at which point of the process falsification is performed.

This concludes the description of the embodiment for carrying out the present invention. The present invention is not limited to the embodiment in any manner, and various kinds of modifications and replacements can be made within a range that does not depart from the gist of the present invention. For example, the present invention can be applied to power conversion equipment and grids, which can be connected to commercial power systems.

What is claimed is:

1. A battery information management method to be executed by at least one computer, the battery information management method comprising:
acquiring battery information including: measurement data including a measurement result relating to electrical characteristics of a battery; an algorithm for evaluating the state of the battery from the measurement data; and evaluation data including the result of evaluating the state of the battery by the algorithm;
executing first processing of calculating a first hash value that is a hash value of at least one of the measurement data and the algorithm included in the battery information;
executing second processing of calculating a second hash value that is a hash value of package data associating the first hash value with the evaluation data; and
executing third processing of storing at least one of the measurement data and the algorithm into a database in a searchable manner with the second hash value serving as a key.

2. The battery information management method according to claim 1, wherein the at least one computer executes the second processing of calculating the second hash value by including, in the package data, data relating to a date and time of acquisition of the battery information or calculation of the first hash value.

3. The battery information management method according to claim 1,
wherein the at least one computer executes the first processing and the second processing every time the measurement result relating to electrical characteristics of the battery is generated, and
wherein the at least one computer executes the third processing of storing, into the database, the first hash and the second hash value, which are calculated by the first processing and the second processing executed for the same battery, in association with each other.

4. The battery information management method according to claim 1,
wherein the at least one computer executes fourth processing of calculating a third hash value that is a hash value of the measurement data in a device including the battery, and
wherein the first processing includes processing of acquiring the third hash value.

5. A non-transitory computer-readable medium storing a program for causing at least one computer to:
acquire battery information including: measurement data including a measurement result relating to electrical characteristics of a battery; an algorithm for evaluating the state of the battery from the measurement data; and evaluation data including the result of evaluating the state of the battery by the algorithm;
execute first processing of calculating a first hash value that is a hash value of at least one of the measurement data and the algorithm included in the battery information;
execute second processing of calculating a second hash value that is a hash value of package data associating the first hash value with the evaluation data; and
execute third processing of storing at least one of the measurement data and the algorithm into a database in a searchable manner with the second hash value serving as a key.
